(19) United States
(12) Patent Application Publication
(10) Pub. No.: US 2018/0138354 A1
(43) Pub. Date: May 17, 2018

(54) SOLAR CELL CURING TOOL

(71) Applicants: SUNPOWER CORPORATION, San Jose, CA (US); TOTAL MARKETING SERVICES, Puteaux (FR)

(72) Inventors: Périne Jaffrennou, Mountain View, CA (US); Gilles Olav Tanguy Sylvain Poulain, Palaiseau (FR); Kieran Mark Tracy, San Jose, CA (US); Taiqing Qiu, Los Gatos, CA (US); Michael C. Johnson, Alameda, CA (US); Seung Bum Rim, Pleasanton, CA (US)

(21) Appl. No.: 15/807,915

(22) Filed: Nov. 9, 2017

Related U.S. Application Data
(60) Provisional application No. 62/421,179, filed on Nov. 11, 2016.

(51) Int. Cl. H01L 31/18; H01L 31/0216

(52) U.S. Cl. CPC H01L 31/1864; H01L 31/022441; H01L 31/02168; H01L 31/1868

(57) ABSTRACT

A curing tool for fabricating solar cells using UV-curing of light-receiving surfaces of the solar cells, and the resulting solar cells, are described herein. In an example, a curing tool combines a UV-exposure stage and one or more of a deposition or an annealing stage to fabricate a solar cell. For example, a radiation curing stage can precede a back end processing stage used to perform operations on a back contact solar cell. The curing tool can therefore be used to perform a method to improve UV stability of solar cells.

### CROSS-REFERENCE TO RELATED APPLICATIONS

This application claims the benefit of U.S. Provisional Application No. 62/421,179, filed on Nov. 11, 2016, the entire contents of which are hereby incorporated by reference herein.

### TECHNICAL FIELD

Embodiments of the present disclosure are in the field of renewable energy and, in particular, UV-curing of light-receiving surfaces of solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

### BRIEF DESCRIPTION OF THE DRAWINGS

FIG. 1 illustrates a schematic view of a curing tool for fabricating a solar cell, in accordance with an embodiment of the present disclosure.

FIGS. 2A-2B illustrate various radiation source configurations of a curing tool for fabricating a solar cell, in accordance with an embodiment of the present disclosure.

FIG. 3 illustrates a side view of a radiation curing stage of a curing tool for fabricating a solar cell, in accordance with an embodiment of the present disclosure.

FIG. 4 illustrates a side view of a portion of a conveyor system of a curing tool for fabricating a solar cell, in accordance with an embodiment of the present disclosure.

FIGS. 5A-5F illustrate cross-sectional views of various stages in the fabrication of a solar cell, in accordance with an embodiment of the present disclosure.

FIGS. 6A-6B illustrate detail views of a holding surface of a wafer platform of a conveyor system, in accordance with an embodiment of the present disclosure.

FIG. 7 illustrates a top view and a cross-sectional view of a wafer platform of a conveyor system, in accordance with an embodiment of the present disclosure.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics can be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. § 112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” conveyor system does not necessarily imply that this conveyor system is the first conveyor system in a sequence; instead the term “first” is used to differentiate this conveyor system from another conveyor system (e.g., a “second” conveyor system).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper” and “lower” refer to directions in the drawings to which reference is made. Terms such as “front,” “back,” “rear,” “side,” “outboard,” and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques and tools for increasing the efficiency in the manufacture of solar cells, are generally desirable. Some embodiments of the present disclosure allow for increased solar cell manufacture efficiency by providing novel tools for fabricating solar cell structures.

Curing tools for fabricating solar cells using UV-curing of light-receiving surfaces of the solar cells, and the resulting solar cells, are described herein. In the following description, numerous specific details are set forth, such as specific process flow operations, in order to provide a thorough understanding of embodiments of the present disclosure. It will be apparent to one skilled in the art that embodiments of the present disclosure can be practiced without these specific details. In other instances, well-known fabrication techniques, such as lithography and patterning techniques, are not described in detail in order to not unnecessarily obscure embodiments of the present disclosure. Furthermore, it is to be appreciated that the various embodiments shown in the figures are illustrative representations and are not necessarily drawn to scale.

To provide context, light induced degradation (LID) and/or ultra-violet (UV) degradation pose long standing issues for the long term stability of solar cell performance. More particularly, lack of UV stability is a failure mode of back contact solar cells, and can be a potential failure mode of front contact solar cells as well. Efforts have been made to improve the stability of such solar cells without compromising performance in the form of decreased passivation or solar spectrum absorption. Performance stability can be critical for performance guarantees and for product quality differentiation. More particularly, front surface passivation can be critical for performance of high efficiency solar cells. Typically, front surface passivation is performed using a diffusion process followed by a high temperature oxidation and, finally, capping with an antireflection coating (ARC) using plasma-enhanced chemical vapor deposition (PECVD). Silicon nitride (SiN or SiN:H) is commonly used as an ARC due to its optical properties and also for its excellent passivation qualities. A silicon nitride layer can be used to provide H+ to a crystalline silicon/thermal oxide (c-Si/TOX) interface. Unfortunately, the interface can be degraded by long term exposure to UV light via hot electron injection across the interface which breaks existing Si—H bonds.

Addressing one or more of the above issues, in accordance with one or more embodiments described herein, efficiency and reliability of a solar cell are improved using a curing tool that can perform a UV-curing operation. In one exemplary embodiment, the curing tool performs a UV curing operation prior to back end processing of a back contact solar cell. For example, UV irradiation can be performed prior to thermal annealing. The curing tool can therefore be used to perform a method to improve UV stability of solar cells.

Not to be bound by theory, in an embodiment, improved stability achieved by intentional UV treatment and thermal anneal results in a more energetically favorable Si—O bonding scenario. Additionally, such treatment can reduce the total number of O—H bonds at the surface of the underlying thermal oxide, reducing the amount of trap states for hot electron trapping and resulting in decreased interface wear.

In one embodiment, a curing tool includes a radiation curing stage, and one or more pre-cure or post-cure stages. For example, the curing tool can include a deposition stage or an annealing stage before or after the radiation curing stage. The curing tool can include a conveyor system having an actuator operably coupled to a wafer platform having a holding surface facing a radiation source. More particularly, the radiation curing stage can include the radiation source to emit electromagnetic radiation. Accordingly, the conveyor system can move the wafer platform continuously through the radiation curing stage and the pre-cure or post-cure stage(s) with a wafer mounted on the holding surface, can receive the emitted electromagnetic radiation.

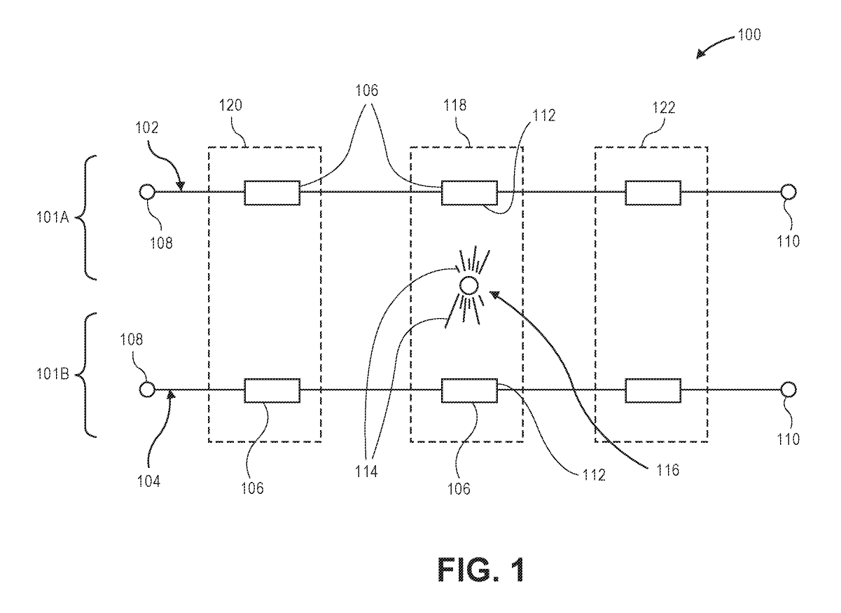

FIG. 1 illustrates a schematic view of a curing tool 100 for fabricating a solar cell. In an embodiment, the curing tool 100 includes one or more conveyor systems, e.g., 102 (as a portion of a first deck 101A) and 104 (as a portion of a second deck 101B), to move a wafer platform 106 between a loading stage 108 and an unloading stage 110. More particularly, the conveyor system 102 or 104 includes an actuator operably coupled to the wafer platform 106 to move the wafer platform 106 continuously through one or more stages between the loading stage 108 and the unloading stage 110. The actuator can include any of several known actuation mechanisms, such as an electric motor, and the actuator can be controlled to move the wafer platform 106 through the stages of the curing tool 100.

The wafer platform 106 can be a supportive structure such as a conveyor belt or a tray on which solar cell substrates or wafers can be placed. More particularly, the wafer platform 106 can have a holding surface 112 to support the wafers. The holding surface 112 can face a direction to receive electromagnetic radiation 114 emitted by a radiation source 116. For example, the curing tool 100 can include a radiation curing stage 118 having the radiation source 116 to emit electromagnetic radiation 114 toward a wafer set on the holding surface 112.

In an embodiment, the radiation source 116 emits electromagnetic radiation 114 including ultraviolet (UV) radiation. For example, the radiation source 116 can include a light emitting diode (LED). The LED can be an UV LED to emit electromagnetic radiation having a wavelength in a range of 330-405 nm. Alternatively, the LED can be a short wavelength visible LED having a wavelength in a range of 400-600 nm. The radiation source can include an arc lamp. For example, the radiation source 116 can be a broadband light source such as a mercury arc lamp or a xenon lamp. It will be appreciated that the examples above are not limiting, and the radiation source 116 can include other radiation devices, such as a laser device or an x-ray tube to emit corresponding types of electromagnetic radiation.

The curing tool 100 can include one or more additional stages other than the radiation curing stage 118. More particularly, the curing tool 100 can include one or more pre-cure stages 120 and one or more post-cure stages 122. By way of example, the pre-cure stage(s) 120 and the post-cure stage(s) 122 can include a deposition stage and/or an annealing stage.

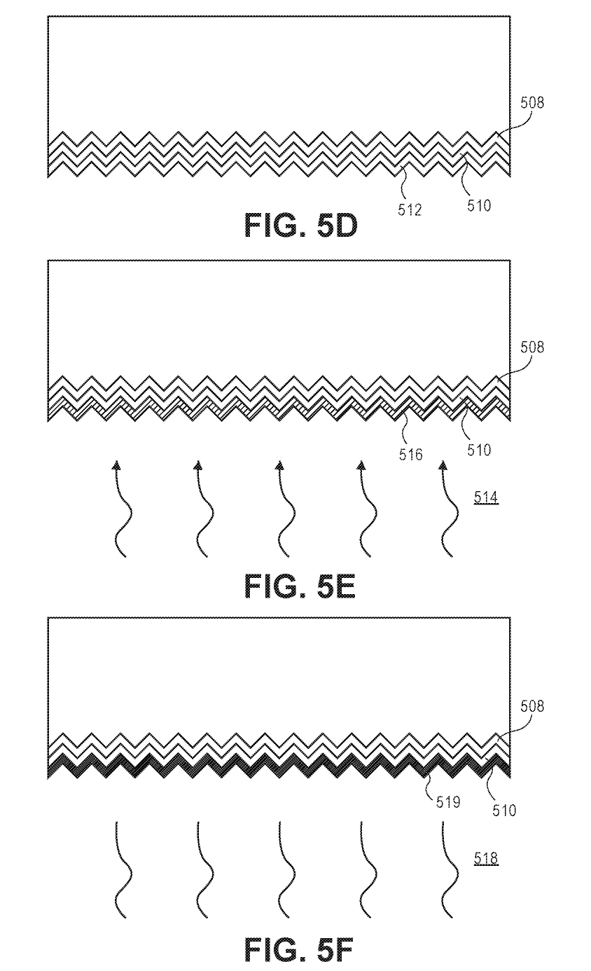

In an embodiment, at least one of the pre-cure stages 120 is a deposition stage. For example, the deposition stage can deposit a passivating dielectric layer on a texturized topography of a light-receiving surface of a starting substrate, e.g., the wafer, of a solar cell. A structure of the solar cell is described further below with respect to FIGS. 5A-5F. Formation of the dielectric layer can include depositing a layer of silicon dioxide (SiO₂) using techniques such as plasma-enhanced chemical vapor deposition (PECVD) of SiO₂, or atomic layer deposition (ALD) of SiO₂ or AlOₓ. Any of these techniques can be performed by the curing tool 100 in the pre-cure stage 120, and more particularly, any deposition technique can be performed by the curing tool 100 in one or more deposition stages prior to moving the substrate into the radiation curing stage 118.

One or more additional pre-cure stages can be incorporated in the curing tool. For example, a pre-cure stage can form an intermediate material layer on the passivated dielectric layer. The additional pre-cure stage can be a deposition stage to form the intermediate material layer using a deposition process such as, but not limited to, plasma-enhanced chemical vapor deposition (PECVD), low pressure chemical vapor deposition (LPCVD), or sputtering (physical vapor deposition, PVD).

One or more of the deposition stages of the curing tool can be an anti-reflective coating (ARC) stage used to form an ARC layer on the optional intermediate material layer or the passivated dielectric layer of the wafer. The ARC stage can include the components necessary to form a silicon nitride layer or a layer of indium tin oxide (ITO). The substrate can be moved into the radiation curing stage after application of the ARC layer to expose the ARC layer to the electromagnetic radiation emitted by the radiation source. More particularly, the ARC layer can face the radiation source to receive the electromagnetic radiation and to form a UV-cured ARC layer.

In an embodiment, at least one of the post-cure stages 122 is an annealing stage. For example, after forming the UV-cured ARC layer on the substrate, the solar cell can be heated. The annealing stage can include the components required to heat the wafer in a range of 200-500 degrees Celsius. Such components can include infrared and/or convective heaters and elements. The components can also include those necessary to perform a forming gas anneal (FGA) process, a rapid thermal anneal (RTA) process, an infra-red (IR) heating process, a furnace heating process, and a laser annealing process. Accordingly, the UV-cured ARC layer can be thermally annealed to form a UV-cured and thermally annealed ARC layer.

The process stages described above can incorporate or be combined with numerous other process stages for forming various portions of a solar cell. For example, the formation of emitter regions on the solar cell can include the formation of one or more conductive layers. Such conductive layers include metal formed by a deposition, lithographic, and etch approach or, alternatively, a printing or plating process or, alternatively, a foil or wire adhesion process. Accordingly, any of these processes can be incorporated in a respective pre-cure stage or post-cure stage of the curing tool.

The fabrication of conductive contacts on the solar cell can involve the inclusion of one or more sputtered, plated, or bonded conductive layers, and the requisite processes can be incorporated in one or more stages of the curing tool. For example, the curing tool can include a seed layer formation stage to fabricate conductive contacts. The seed layer formation stage can include the components required to deposit a blanket layer of metal-based layers, e.g., aluminum-based layers, that can be patterned later using a deposition, lithographic, or etch approach.

The curing tool 100 can incorporate a photoluminescence (PL) detection system in a pre-cure stage 120 or a post-cure stage 122. That is, PL detection can occur before the cure and post-cure to confirm that a surface of the wafer is depassivated. One or more PL detectors can be located at several locations throughout the process, e.g., between the loading stage and the unloading stage, or the detector(s) can be co-located at a single location at the end of the curing tool, e.g., at or adjacent to the unloading stage. A light source used to irradiate the wafer to perform the PL detection can be the same source used to perform the radiative interface cure. More particularly, the radiation source of the radiation curing stage can provide the requisite light to perform PL detection on the wafer. Accordingly, in an embodiment, a separate light source for the PL detection is not necessary.

The conveyor system 102 and/or 104 of the curing tool 100 can transfer the wafer platform 106 continuously through the various stages described above. For example, the conveyor system 102 and/or 104 can move the wafer platform 106 continuously through the radiation curing stage 118 and one or more of the deposition stages or the annealing stage. Accordingly, the wafer mounted on the wafer platform 106 can be set on the holding surface 112 and sequentially processed in a single process flow to: deposit various layers, e.g., the ARC layer, on a starting substrate; to irradiate and cure the various layers, e.g., using UV radiation; and to anneal the cured wafer layers.

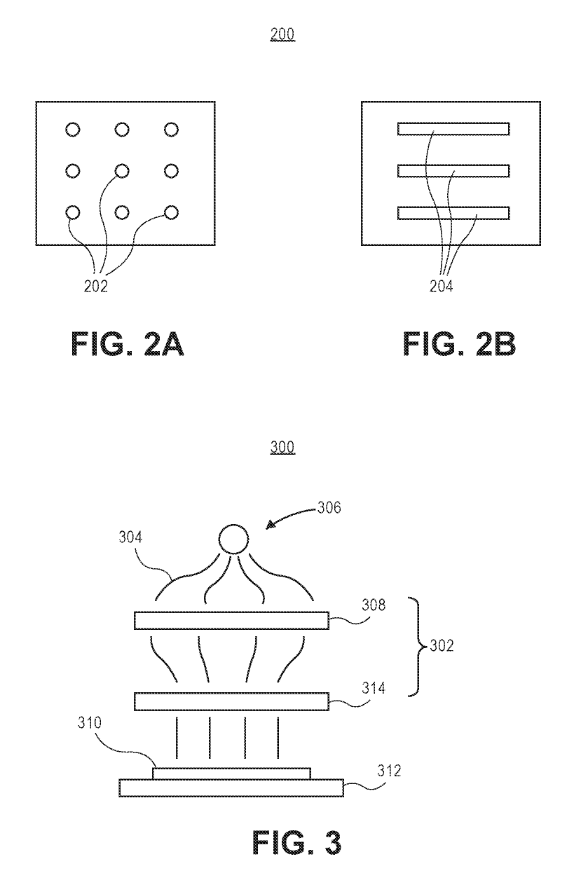

FIGS. 2A-2B illustrate various radiation source 200 configurations of a curing tool for fabricating a solar cell. Referring to FIG. 2A, in an embodiment, the radiation source 200 of the curing tool includes an array of LEDs 202. Alternatively, as shown in FIG. 2B, the radiation source 200 of the curing tool includes several lines of broadband light sources such as arc lamps 204. The array and/or lines can be arranged to control a total dose of electromagnetic radiation emitted toward the wafer platforms. More particularly, the arrangement of radiation source can manage the total dose of radiation, e.g., UV radiation, used to irradiate the wafers being carried by the wafer platform.

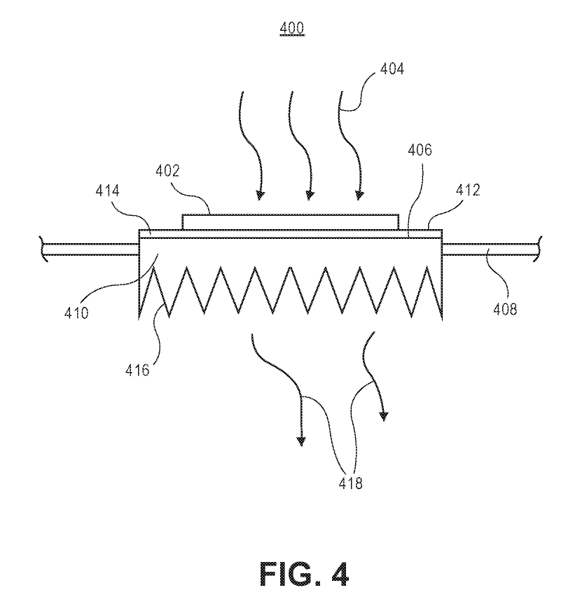

FIG. 3 illustrates a side view of a radiation curing stage 300 of a curing tool for fabricating a solar cell. In an embodiment, the radiation curing stage 300 includes optics 302 to control the directionality and/or intensity of electromagnetic radiation 304 from a radiation source 306. For example, an optics stack 302 can include a distribution lens 308 to redirect, e.g., converge, light from the radiation source 306 toward a wafer 310 mounted on a wafer holder 312. The redistribution of the electromagnetic radiation 304 can uniformly distribute radiant energy over the wafer 310. The optics stack 302 can include additional elements, such as a collimation lens 314 used to collimate the electromagnetic radiation 304 such that the radiation impinges directly on a surface of the wafer 310. Thus, the optics stack 302 can include one or more elements to direct UV radiation orthogonal to, and evenly across, the wafer surface.

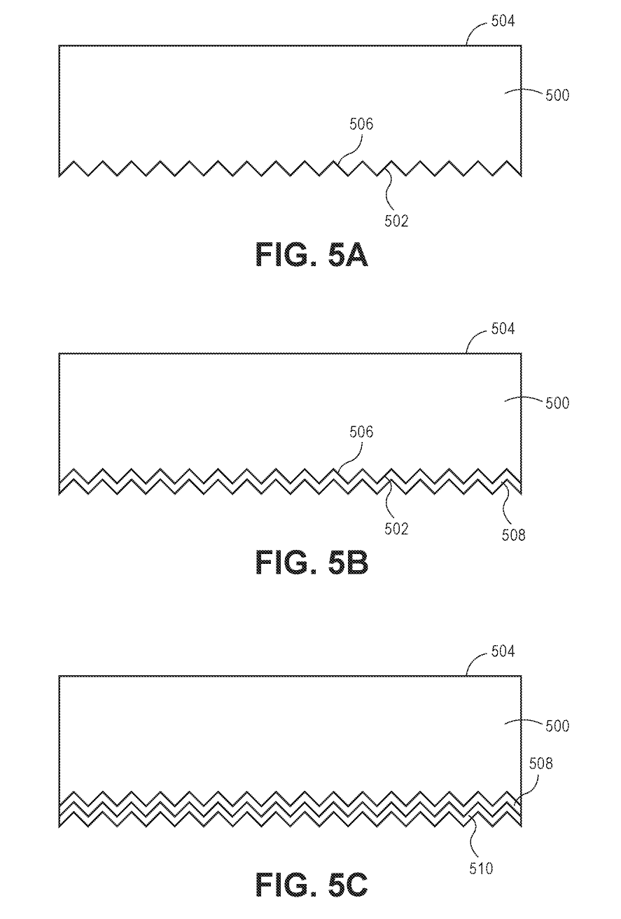

FIG. 4 illustrates a side view of a portion 400 of a conveyor system of a curing tool for fabricating a solar cell 402. Components of the curing tool intended for use within the radiation curing stage can be configured to resist the electromagnetic radiation 404. For example, the wafer holder 406, the conveyor belt, or a tray of the conveyor system 408, which traverses the radiation curing stage, can be fabricated from a metal or a plastic body 410 that is resistant to radiation having the given wavelength of the electromagnetic radiation 404. By way of example, the wafer platform 412 can have a metal body (e.g., 410) covered by a plastic coating 414, e.g., over the holding surface 406, to resist degradation caused by the UV irradiation from the electromagnetic radiation 404.

In an embodiment, the wafer platform includes a heat exchanger 416 to transfer heat 418 from the received electromagnetic radiation into a surrounding environment. By way of example, the heat exchanger 416 can include a passive heat sink to reduce heat accumulation in the wafer mounted on the holding surface. The passive heat sink can include an aluminum plate and/or cooling fins such that radiant heat from the electromagnetic radiation is conductively transferred from the wafer to the metal body and then convectively transferred from the metal body to the surrounding environment. The heat exchanger can incorporate active cooling elements. For example, fluid cooling pipes can extend over or through the metal body such that conducted heat is transferred into a fluid, e.g., water, flowing through the pipes and away from the wafer.

Referring again to FIG. 1, the curing tool can be configured to minimize tool cost. For example, the radiation source of the radiation curing stage can simultaneously irradiate several wafers. In an embodiment, the curing tool includes a second conveyor system 104 carrying a second layer of wafers. More particularly, the second conveyor system 104 can include a second wafer platform 106 having a second holding surface 112 facing the radiation source 116. The radiation source 116 can be between the holding surface 112 of the first wafer platform 106 and the second holding surface 112 of the second wafer platform 106. For example, the conveyor system can convey the wafer platform above the radiation source and the second conveyor system can convey the second wafer platform below the radiation source. Accordingly, a first wafer mounted on the holding surface of the wafer platform can receive electromagnetic radiation emitted by the radiation source in a first direction, e.g., an upward direction, and a second wafer mounted on the second holding surface of the second wafer platform can receive electromagnetic radiation emitted by the radiation source in a second direction, e.g., a downward direction. The layers of wafers can be irradiated simultaneously, and thus, a single radiation source can be used to cure several wafers. Accordingly, tool cost can be minimized as compared to a curing tool having dedicated light sources for each layer of wafers.

The curing tool 100 can also minimize footprint by incorporating several layers of wafers. For example, the conveyor system can convey the wafer platform in a first deck above radiation source and the second conveyor system can convey second wafer platform in a second deck below the radiation source. Here the terms “above” and “below” refer to respective directions from the radiation source, i.e., on different sides of the radiation source. Accordingly, several curing decks can be stacked vertically within a same footprint. Given that space within a manufacturing facility has an associated cost, the curing tool having several curing decks can provide a manufacturing efficiency.

In an embodiment, the curing tool can incorporate multiple lanes per deck to minimize tool cost and/or footprint. For example, the first deck or the second deck can incorporate several conveyor systems arranged in parallel. The conveyor systems can share one or more components. For example, each conveyor system can have a respective conveyor belt, and the conveyor belts can be driven by a same actuator. Accordingly, different wafers can be carried by the respective conveyor belts using a single actuator. Similar to the shared radiation source as described above with respect to some embodiments, sharing conveyor mechanisms can reduce tool costs and/or size.

Referring to FIGS. 5A-5F, cross-sectional views of various stages in the fabrication of a solar cell are illustrated. The stages may be performing using the curing tool. FIG. 5A illustrates a starting substrate of a solar cell. Referring to FIG. 5A, substrate 500 has a light-receiving surface 502 and a back surface 504. In an embodiment, the substrate 500 is a monocrystalline silicon substrate, such as a bulk single crystalline N-type doped silicon substrate. It is to be appreciated, however, that substrate 500 can be a layer, such as a multi-crystalline silicon layer, disposed on a global solar cell substrate. In an embodiment, the light-receiving surface 502 has a texturized topography 506.

FIG. 5B illustrates the structure of FIG. 5A following formation of a passivating dielectric layer on a light-receiving surface of the substrate. In an embodiment, a passivating dielectric layer 508 is formed on the light-receiving surface 502 of substrate 500 in a deposition stage of the curing tool. In one embodiment, the light-receiving surface 502 has a texturized topography 506, and the passivating dielectric layer 508 is conformal with the texturized topography 506, as is depicted in FIG. 5B.

In an embodiment, the passivating dielectric layer 508 is a layer of silicon dioxide (SiO₂). In one such embodiment, the layer of silicon dioxide (SiO₂) has a thickness approximately in the range of 10-400 Angstroms. In one embodiment, the passivating dielectric layer 508 is hydrophilic. In an embodiment, the passivating dielectric layer 508 is formed by a technique such as, but not limited to, chemical oxidation of a portion of the light-receiving surface of the silicon substrate, plasma-enhanced chemical vapor deposition (PECVD) of silicon dioxide (SiO₂), thermal oxidation of a portion of the light-receiving surface of the silicon substrate, atomic layer deposition (ALD) of SiO₂, or exposure of the light-receiving surface of the silicon substrate to ultra-violet (UV) radiation in an O₂ or O₃ environment. In a specific embodiment, the passivating dielectric layer 508 is a thermal silicon oxide layer formed on the light-receiving surface of an N-type monocrystalline silicon substrate. In another specific embodiment, the passivating dielectric layer 508 is formed by atomic layer deposition (ALD), and is a silicon oxide passivating dielectric layer.

FIG. 5C illustrates the structure of FIG. 5B following optional formation of an intermediate material layer on the passivating dielectric layer. In an embodiment, an intermediate material layer (or layers) 510 is formed on the passivating dielectric layer 508 in a deposition stage of the curing tool. In one embodiment, as is depicted in FIG. 5C, the intermediate material layer (or layers) 510 is conformal with the texturized topography 506.

In an embodiment, the intermediate material layer (or layers) 510 is or includes an N-type micro- or poly-crystalline silicon layer formed on the passivating dielectric layer 508. In one such embodiment, the N-type micro- or poly-crystalline silicon layer has a thickness approximately in the range of 1-20 nanometers. In one embodiment, the N-type micro- or poly-crystalline silicon layer has a crystalline fraction approximately in the range of 0.1-0.9 (i.e., 10-90%), with the balance being amorphous. In an embodiment, a concentration of N-type dopants (e.g., phosphorous) in the N-type micro- or poly-crystalline silicon layer is approximately in the range of 1E17-1E20 atoms/cm³. In one embodiment, the N-type micro- or poly-crystalline silicon layer includes small grains having a micro- or nano-diameter. The small grains can be embedded in a generally amorphous silicon matrix and have essentially no long range order. In an embodiment, the N-type dopants are included in the amorphous portion, in the crystalline portion, or both.

In an embodiment, the N-type micro- or poly-crystalline silicon layer is formed by depositing an N-type amorphous silicon layer and, subsequently, phase converting the N-type amorphous silicon layer to the N-type micro- or poly-crystalline silicon layer. In one such embodiment, the N-type amorphous silicon layer is formed by a deposition process such as, but not limited to, plasma-enhanced chemical vapor deposition (PECVD), low pressure chemical vapor deposition (LPCVD), or sputtering (physical vapor deposition, PVD). In one embodiment, the phase conversion is achieved using a technique such as, but not limited to, heating in a furnace, rapid thermal processing (RTP), laser annealing, or forming gas annealing (FGA). In another embodiment, the N-type micro- or poly-crystalline silicon layer is formed by depositing the N-type micro- or poly-crystalline silicon layer. In one such embodiment, the N-type micro- or poly-crystalline silicon layer is deposited using PECVD.

In another embodiment, the intermediate material layer (or layers) 510 is or includes an N-type amorphous silicon layer. In one embodiment, forming the N-type amorphous silicon layer is performed at a temperature less than approximately 400 degrees Celsius. In an embodiment, the N-type amorphous silicon layer is formed using plasma enhanced chemical vapor deposition (PECVD), represented by phosphorous-doped a-Si:H, which includes Si—H covalent bonds throughout the layer. In either case, in an embodiment, the N-type micro- or poly-crystalline or amorphous silicon layer 512 includes an impurity such as phosphorous dopants. In one such embodiment, the phosphorous dopants are incorporated either during film deposition or in a post implantation operation.

In another embodiment, the intermediate material layer (or layers) 510 is or includes a layer such as, but not limited to, an amorphous silicon (a-Si) layer, a silicon-rich silicon nitride layer, or a Group III-V material layer. In one embodiment where the intermediate material layer (or layers) 510 is or includes a Group III-V material layer, the Group III-V material layer is a layer such as, but not limited to, a GaP layer, an AlGaP layer, a GaAs layer, an InGaAs layer, a GaN layer, or an AlGaN layer.

FIG. 5D illustrates the structure of FIG. 5C following formation of an anti-reflective coating (ARC) layer on the optional intermediate material layer. In an embodiment, an anti-reflective coating (ARC) layer 512 is formed on the intermediate material layer (or layers) 510 in a deposition stage of the curing tool. It is to be appreciated that the intermediate material layer (or layers) 510 can be omitted and, in one embodiment, the ARC layer 512 is formed directly on the passivating dielectric layer 508. In either case, in one embodiment, as is depicted in FIG. 5D, the ARC layer 512 is conformal with the texturized topography 506, e.g., of FIG. 5B.

In an embodiment, the ARC layer 512 is a non-conductive ARC layer. In one such embodiment, the non-conductive ARC layer 512 is or includes a silicon nitride layer. In a particular such embodiment, the silicon nitride is formed at a temperature less than approximately 400 degrees Celsius. In another embodiment, the ARC layer 512 is or includes a layer of aluminum oxide (AlOₓ). In another embodiment, the ARC layer 512 is a conductive ARC layer. In one such embodiment, the conductive ARC layer includes a layer of indium tin oxide (ITO).

In an embodiment, the ARC layer 512 is formed having an amount of hydrogen therein. In one such embodiment, the fabrication process further includes removing at least a portion of the amount of hydrogen from the ARC layer 512 after deposition of the ARC layer 512. In a specific such embodiment, the portion of the amount of hydrogen from the ARC layer 512 is removed during the thermal annealing process described below in association with FIG. 5F.

FIG. 5E illustrates the structure of FIG. 5D following exposure of the ARC layer to ultra-violet (UV) radiation. In an embodiment, the ARC layer 512 is exposed to ultra-violet (UV) radiation 514 in a radiation curing stage of the curing tool. In an embodiment, the exposure of the ARC layer 512 to the UV radiation 514 forms a UV-cured ARC layer 516.

It is to be appreciated that although the exposure to UV radiation 514 is depicted herein as being performed following formation of the ARC layer 512, such a UV cure can be performed at other stages of the process flow. For example, in a first alternative embodiment, a UV cure is performed subsequent to forming the passivating dielectric layer 508 but prior to forming the ARC layer 512. In one such alternative embodiment, a UV cure is performed subsequent to forming the passivating dielectric layer 508 but prior to forming intermediate material layer (or layers) 510. In another such alternative embodiment, a UV cure is performed subsequent to forming the passivating dielectric layer 508 and forming intermediate material layer (or layers) 510.

In an embodiment, exposing the ARC layer 512 to UV radiation involves exposing the ARC layer 512 to light having a wavelength approximately in the range of 250-450 nanometers. In an embodiment, exposing the ARC layer 512 to UV radiation involves exposing the ARC layer 512 to the UV radiation 514 for a duration approximately in the range of 1 second-1 day. In an embodiment, subsequent to forming the ARC layer 512 but prior to exposing the ARC layer 512 to the UV radiation 514, the solar cell is heated at a temperature approximately in the range of 200-500 degrees Celsius. Such heating can be performed in a heating stage of the curing tool.

FIG. 5F illustrates the structure of FIG. 5E following thermal annealing of the ARC layer. In an embodiment, the UV-cured ARC layer 516 is thermally annealed using thermal radiation 518 in an annealing stage of the curing tool. In an embodiment, the thermal annealing of the UV-cured ARC layer 516 forms a UV-cured and thermally annealed ARC layer 519.

In an embodiment, the ARC layer is thermally annealed by heating at a temperature approximately in the range of 200-500 degrees Celsius. In an embodiment, the ARC layer is thermally annealed using a process such as, but not limited to, a forming gas anneal (FGA) process, a rapid thermal anneal (RTA) process, an infra-red (IR) heating process, a furnace heating process, and a laser annealing process.

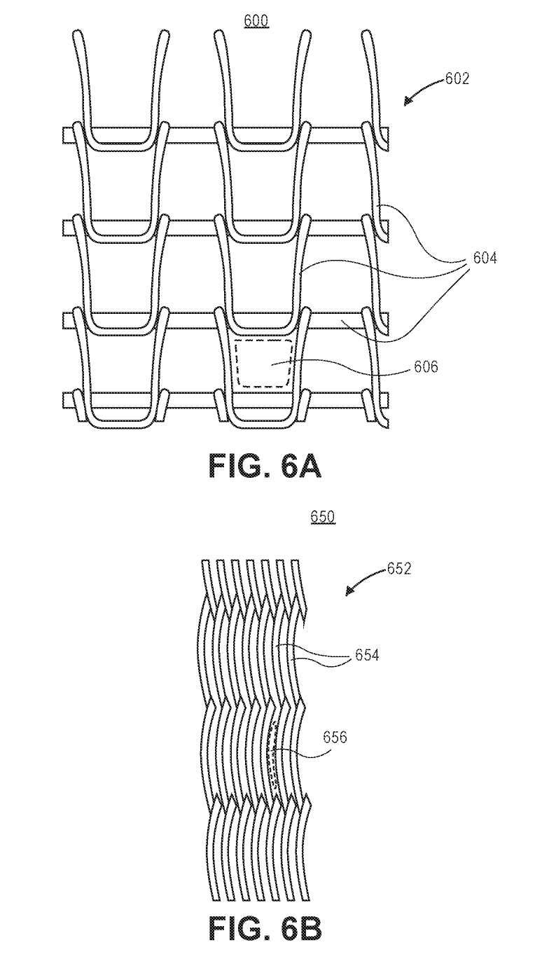

Referring to FIGS. 6A-6B, detail views of a holding surface of a wafer platform of a conveyor system is illustrated. For certain applications, UV heating may be used, and wafers may be exposed to UV radiation at elevated temperatures. As shown in FIG. 6A, the wafer platform 600 may include a loosely-packed belt 602, and the belt surface may provide the holding surface to support the wafer. More particularly, the belt 602 may have a fabric 604, a mesh, etc., fabricated from woven or interlaced elements. The fabric 604 may include an interstitial space 606 between the interlaced elements. The interstitial space 606 may be sized to allow UV radiation to impinge on a surface of the wafer supported on the waver platform. That is, the loosely-packed belt 602 may have pores or openings that do not block radiation to allow the electromagnetic radiation to transmit through the wafer platform to effectively irradiate and/or heat the wafer surface.

Referring to FIG. 6B, when UV heating is not used, the conveyor system 650 may include a densely packed belt 652. The densely packed belt 652 may have a fabric 654 with smaller interstitial spaces 656. Accordingly, a contact area between a surface of the supported wafer and a holding surface of the densely packed belt 652 may be greater than a comparative contact area between the surface of a supported wafer and a holding surface of a loosely-packed belt. The densely packed belt may therefore provide greater wafer support and increase conductive heat transfer to the wafer, as compared to the loosely-packed belt, in processes not including UV heating.

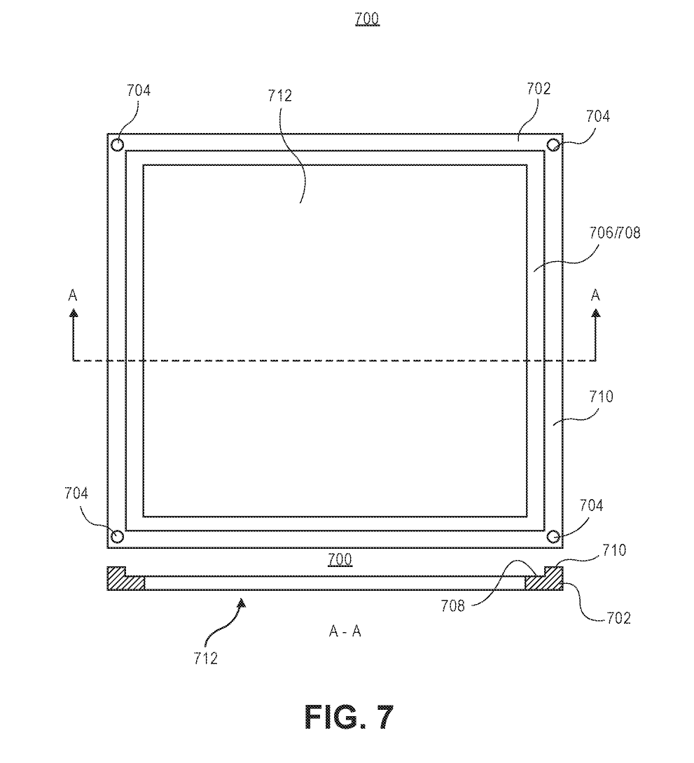

Referring to FIG. 7, a top view and a cross-sectional view of a wafer platform 700 of a conveyor system is illustrated. The wafer platform 700 may include a rigid frame 702, e.g., fabricated from an aluminum alloy, to support the wafer during the operations performed by the curing tool. The wafer platform 700 may include fastener holes 704 to connect the wafer platform to a conveyor component, such as a belt, chain, etc. The holding surface 706 of the wafer platform may include a support ledge 708 upon which an edge of the wafer may rest. Lateral movement of the wafer may be constrained by a registration lip 710 of the wafer platform. That is, a rim of the wafer may be coplanar with the registration lip 710 when a bottom surface of the wafer rests on the support ledge. Thus, the wafer may be cradled in the wafer platform for transport through the curing tool.

In an embodiment, the wafer platform includes an irradiation channel 712. The irradiation channel 712 may be a hole aligned along a vertical axis with a back side of the wafer. Accordingly, the electromagnetic radiation may pass through the irradiation channel to cure the back side of the wafer.

In an embodiment, curing and/or heating of the back side of the wafer may be unnecessary, and thus, the irradiation channel may be omitted. That is, the wafer platform may have a closed pocket with a solid back surface extending laterally between the registration lips. The solid back surface may include the holding surface to support the wafer. The solid back surface may also transfer heat conductively to the wafer surface.

A rate of movement of conveyor system may be controlled to achieve a desired curing result. More particularly, the rate of movement of the conveyor system may be controlled to accumulate a predetermined amount of electromagnetic radiation in the wafer within the radiation curing stage. It will be appreciated that the predetermined amount may vary from process to process, and that motion of a conveyor belt may controlled by increasing or decreasing a speed of actuation of the actuator that is operably coupled to the wafer platform. In an embodiment, the actuator of the conveyor system may be stopped when the wafer platform is within the radiation curing stage to pause for the electromagnetic radiation to impinge on a supported wafer. Accordingly, the supported wafer may accumulate a predetermined light dose during the curing operation. After dosing is complete, the actuator may be restarted to convey the wafer platform toward the unload stage of the curing tool.

Although certain materials are described specifically with reference to the above described embodiments, some materials can be readily substituted with others with such embodiments remaining within the scope of the present disclosure. For example, in an embodiment, a different material substrate, such as a group III-V material substrate, can be used instead of a silicon substrate. Additionally, although reference is made to back contact solar cell arrangements, it is to be appreciated that approaches described herein can have application to front contact solar cells or bifacial architectures as well. In other embodiments, the above described approaches can be applicable to manufacturing of other than solar cells. For example, manufacturing of light emitting diode (LEDs) can benefit from approaches described herein.

Thus, curing tools for fabricating solar cells using UV-curing of light-receiving surfaces of the solar cells, and the resulting solar cells, have been disclosed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims can be formulated during prosecution of the present application (or an application claiming priority thereto) to any such combination of features. In particular, with reference to the appended claims, features from dependent claims can be combined with those of the independent claims and features from respective independent claims can be combined in any appropriate manner and not merely in the specific combinations enumerated in the appended claims.

What is claimed is:

1. A solar cell curing tool, comprising:
a radiation curing stage including a radiation source to emit electromagnetic radiation;
one or more of a deposition stage or an annealing stage; and
a conveyor system including an actuator operably coupled to a wafer platform, wherein the wafer platform has a holding surface facing the radiation source to receive the emitted electromagnetic radiation, and wherein the conveyor system moves the wafer platform through the radiation curing stage and the one or more of the deposition stage or the annealing stage.

2. The solar cell curing tool according to claim 1, wherein the radiation source includes one or more of a light emitting diode or an arc lamp, and wherein the electromagnetic radiation includes ultraviolet radiation.

3. The solar cell curing tool according to claim 2, wherein the radiation source includes the light emitting diode.

4. The solar cell curing tool according to claim 2, wherein the radiation source includes the arc lamp.

5. The solar cell curing tool according to claim 2, wherein the wafer platform includes a loosely-packed belt.

6. The solar cell curing tool according to claim 1, wherein the wafer platform includes a heat exchanger to transfer heat from the received electromagnetic radiation into a surrounding environment.

7. The solar cell curing tool according to claim 6, wherein the heat exchanger includes a heat sink.

8. The solar cell curing tool according to claim 1 further comprising a second conveyor system including a second wafer platform, wherein the second wafer platform has a second holding surface facing the radiation source to receive the emitted electromagnetic radiation, and wherein the radiation source is between the holding surface and the second holding surface.

9. The solar cell curing tool according to claim 1, wherein a rate of movement of the conveyor system is controlled when the wafer platform is within the radiation curing stage to accumulate a predetermined amount of electromagnetic radiation in a wafer supported by the wafer platform.

10. The solar cell curing tool according to claim 1, further comprising a photoluminescence detector, wherein the photoluminescence detector is configured to detect whether a surface of a wafer mounted on the wafer platform is depassivated.

11. A method of fabricating a solar cell, the method comprising:
transporting a wafer through a radiation curing stage of a curing tool, the radiation curing stage including a radiation source to emit electromagnetic radiation; and
transporting the wafer through one or more of a deposition stage or an annealing stage of the curing tool, wherein transporting the wafer comprises using a conveyor system including an actuator operably coupled to a wafer platform, wherein the wafer platform has a holding surface facing the radiation source to receive the emitted electromagnetic radiation, and wherein the conveyor system moves the wafer platform through the radiation curing stage and the one or more of the deposition stage or the annealing stage.

12. The method according to claim 11, wherein the radiation source includes one or more of a light emitting diode or an arc lamp, and wherein the electromagnetic radiation includes ultraviolet radiation.

13. The method according to claim 12, wherein the radiation source includes the light emitting diode.

14. The method according to claim 12, wherein the radiation source includes the arc lamp.

15. The method according to claim 12, wherein the wafer platform includes a loosely-packed belt.

16. The method according to claim 11, wherein the wafer platform includes a heat exchanger to transfer heat from the received electromagnetic radiation into a surrounding environment.

17. The method according to claim 16, wherein the heat exchanger includes a heat sink.

18. The method according to claim 11, further comprising transporting a second wafer using a second conveyor system including a second wafer platform, wherein the second wafer platform has a second holding surface facing the radiation source to receive the emitted electromagnetic radiation, and wherein the radiation source is between the holding surface and the second holding surface.

19. The method according to claim 11, wherein a rate of movement of the conveyor system is controlled when the wafer platform is within the radiation curing stage to accumulate a predetermined amount of electromagnetic radiation in the wafer supported by the wafer platform.

20. The method according to claim 11, further comprising transporting the wafer through a photoluminescence detector, wherein the photoluminescence detector is configured to detect whether a surface of the wafer mounted on the wafer platform is depassivated.
